(19) United States
(12) Patent Application Publication
(10) Pub. No.: US 2014/0218025 A1
(43) Pub. Date: Aug. 7, 2014

(54) TRANSVERSE VOLUME COILS AND RELATED MAGNETIC RESONANCE SYSTEMS AND METHODS

(71) Applicant: AGILENT TECHNOLOGIES, INC., Loveland, CO (US)

(72) Inventor: WAI HA WONG, SAN JOSE, CA (US)

(73) Assignee: AGILENT TECHNOLOGIES, INC., Loveland, CO (US)

(21) Appl. No.: 13/757,107

(22) Filed: Feb. 1, 2013

(51) Int. Cl. G01R 33/341; G01R 33/44

(52) U.S. Cl. CPC G01R 33/341; G01R 33/44
USPC 324/309; 324/322

(57) ABSTRACT

A transverse volume magnetic resonance (MR) coil includes a cylindrical geometry of electrical conductors configured for generating a B₁ field comprising nth mode spatial harmonics along a first transverse axis in a transverse plane orthogonal to a central axis of the coil, while being uniform along a second transverse axis orthogonal to the first transverse axis in the transverse plane, where n is an integer ranging from 1 or greater. The coil may be included with other coils in an array coil. The coil may be utilized to detect geometric echoes resulting from excitation of an MR sample.

### TECHNICAL FIELD

The present invention relates generally to magnetic resonance (MR) technology such as magnetic resonance imaging (MRI) and nuclear magnetic resonance (NMR) spectrometry. More particularly, the invention relates to volume coils for use as radio frequency (RF) receive coils or transmit/receive coils in MR applications.

### BACKGROUND

A magnetic resonance (MR) system is utilized to obtain useful information from a sample of interest. The sample may be a chemical specimen (e.g., a contained liquid or solid object) or a biological organism (e.g., a human or animal). An MR system may be configured as a nuclear magnetic resonance (NMR) spectrometer that obtains spectral data indicative of molecular structure, position and abundance. An MR system may also be configured as a magnetic resonance imaging (MRI) apparatus that obtains imaging data indicative of the position and pathology of tissues and organs.

In a typical MR system, the sample is loaded into the bore of a cylindrical radio frequency (RF) coil or an array of RF coils, or positioned adjacent to one or more surface coils. The sample and RF coil(s) are positioned in the bore of a (typically superconducting) magnet that generates a high-strength (typically a few to several Tesla) static magnetic field, or Bₒ field, along the central axis of the magnet bore, or z-axis. MR-active nuclei of the sample, such as protons (hydrogen nuclei), behave as magnetic dipoles and become aligned with the B₀ field along the z-axis. One of the RF coils is utilized as a transmit coil to apply a pulsed magnetic field, or B₁ field, to the sample. The B₁ field is typically orthogonal to the B₀ field and oscillates in the RF range (i.e., on the order of MHz). The transmit coil is tuned to resonantly excite the protons or other MR-active nuclei of interest in the sample. The resonance condition is fulfilled when the frequency of the applied B₁ field equals the Larmor frequency of the nucleus of interest. The Larmor frequency, ν, depends on the type of nucleus and the strength of the B₀ field as follows: ν=(γB₀)/2π, where γ is the gyromagnetic ratio of the nucleus and B₀ is the magnitude of the B₀ field. At resonance, the B₁ field efficiently transfers electromagnetic energy to the nucleus and causes a change in energy state. During the delay interval between pulses the nucleus emits an RF time-domain signal, known as a free-induction decay (FID), as a result of this perturbation. The FID decays in the interval as the excited nucleus relaxes back to its equilibrium state. The FID is picked up as an MR measurement signal by the RF coil (the same coil utilized for excitation or a different coil).

Electronics of the MR system amplify and process the MR measurement signal, including converting the signal from the time domain to frequency domain by Fourier transformation. In an NMR instrument, the data is processed to construct an NMR spectrum in the frequency domain. The spectrum consists of one or more peaks whose intensities represent the proportions of each frequency component detected. In an MRI instrument, gradient coils are utilized to apply linear magnetic field gradients to the B₀ field at appropriate times along the x-, y- and z-axes to vary the Larmor frequency of nuclei in a spatially dependent manner. The field gradients are utilized to perform slice selection, phase encoding and frequency encoding techniques enabling construction of three-dimensional images of the interior of the sample, as appreciated by persons skilled in the art.

New fast-imaging techniques such as simultaneous acquisition of spatial harmonics (SMASH) or sensitivity encoding for fast MRI (SENSE) use multiple surface coils to detect MRI signals from the same or different parts of the sample simultaneously. When combined with a parallel imaging reconstruction method such as generalized autocalibrating partially parallel acquisitions (GRAPPA), imaging speed can be increased significantly. These methods have been used routinely in clinical settings.

Currently, the parallel imaging technique is only applied with a surface coil array. A volume coil array to detect the same part of a sample has never been introduced due to the inter-coil-coupling challenge. A coil structure and detection method entailing the use of a volume array coil for parallel imaging has recently been disclosed in U.S. patent application Ser. No. 13/584,126, titled “PARALLEL MAGNETIC RESONANCE IMAGING USING GLOBAL VOLUME ARRAY COIL,” filed Aug. 13, 2012, the entire content of which is incorporated by reference herein. Coils for acceleration of imaging speed along the z-axis (i.e., the longitudinal axis of the coil volume, parallel to the static B₀ field) were introduced in that disclosure. However, acceleration in the transverse plane, i.e., along the x-axis or y-axis, is not possible in the arrangement described in that disclosure.

There is a need for volume coils and methods for accelerating imaging speed or acquisition of MR measurement signals in directions transverse to z-axis.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one embodiment, a transverse volume magnetic resonance (MR) coil includes: an electrically conductive upper ring coaxial with a central axis; an electrically conductive lower ring coaxial with the central axis and axially spaced from the upper ring; and a plurality of electrically conductive legs extending through a cylindrical region axially disposed between the upper ring and the lower ring, wherein the legs are arranged in a geometry configured for generating a B₁ field comprising nth mode spatial harmonics along a first transverse axis in a transverse plane orthogonal to the central axis, where n is an integer ranging from 1 or greater, and wherein the B₁ field is uniform along a second transverse axis orthogonal to the first transverse axis in the transverse plane.

According to another embodiment, a transverse volume magnetic resonance (MR) coil includes: a plurality of coil segments circumferentially spaced about a central axis and surrounding a cylindrical volume, each coil segment spaced from an adjacent coil segment by a longitudinal gap parallel to the central axis; and a plurality of electrically conductive crossmembers. Each coil segment includes: an electrically conductive upper ring segment; an electrically conductive lower ring segment axially spaced from the upper ring segment; a plurality of electrically conductive upper legs extending from the upper ring segment toward the lower ring segment; and a plurality of electrically conductive lower legs extending from the lower ring segment toward the upper ring segment. Each cross-member interconnects an end of a respective lower ring segment with an end of the upper ring segment of an adjacent coil segment, and extends in a direction traversing a corresponding longitudinal gap.

According to another embodiment, a transverse volume magnetic resonance (MR) coil includes: an electrically conductive upper ring coaxial with a central axis, the upper ring comprising a plurality of upper ring segments, each upper ring segment terminating at two ends, wherein each end of each upper ring segment is spaced from a corresponding end of an adjacent upper ring segment by a circumferential upper gap; an electrically conductive lower ring coaxial with the central axis and spaced from the upper ring by a cylindrical region, the lower ring comprising a plurality of lower ring segments, each lower ring segment terminating at two ends, wherein each end of each lower ring segment is spaced from a corresponding end of an adjacent lower ring segment by a circumferential lower gap; a plurality of electrically conductive upper legs and lower legs extending through the cylindrical region in an interdigitated manner, wherein different groups of upper legs extend from respective upper ring segments toward a corresponding lower ring segment and different groups of lower legs extend from respective lower ring segments toward a corresponding upper ring segment, and wherein each upper ring segment, corresponding lower ring segment, and corresponding groups of upper legs and lower legs between the upper ring segment and corresponding lower ring segment forms a cylindrical coil segment; and a plurality of electrically conductive cross-members extending through the cylindrical region such that each end of each lower ring segment electrically communicates with a corresponding end of the upper ring segment of an adjacent coil segment.

According to another embodiment, a transverse volume magnetic resonance (MR) coil includes: an electrically conductive upper ring coaxial with a central axis, the upper ring comprising a first upper ring half terminating at two ends and a second upper ring half terminating at two ends, wherein each end of the first upper ring half is spaced from a corresponding end of the second upper ring half by a circumferential upper gap; an electrically conductive lower ring coaxial with the central axis and spaced from the upper ring by a cylindrical region, the lower ring comprising a first lower ring half terminating at two ends and a second lower ring half terminating at two ends, wherein each end of the first lower ring half is spaced from a corresponding end of the second lower ring half by a circumferential lower gap; a plurality of electrically conductive cross-members extending through the cylindrical region such that each end of the first lower ring half electrically communicates with a corresponding end of the second upper ring half, and each end of the first upper ring half electrically communicates with a corresponding end of the second lower ring half; and a plurality of electrically conductive upper legs and lower legs extending through the cylindrical region in an interdigitated manner, wherein the upper legs communicate with the upper ring and extend toward the lower ring and the lower legs communicate with the lower ring and extend toward the upper ring.

According to another embodiment, a transverse volume magnetic resonance (MR) array coil includes a plurality of cylindrical coils concentric with each other and coaxial with a common central axis, wherein at least one of the coils is a transverse volume MR coil.

According to another embodiment, a transverse volume magnetic resonance (MR) array coil includes: a first coil comprising a cylindrical first geometry of electrical conductors coaxial with a central axis, wherein the first geometry is configured for generating a B₁ field that is uniform throughout a transverse plane orthogonal to the central axis; and a second coil comprising a cylindrical second geometry of electrical conductors concentric with the first coil relative to the central axis, wherein the second geometry is configured for generating a B1 field comprising nth mode spatial harmonics along a first transverse axis in the transverse plane while being uniform along a second transverse axis orthogonal to the first transverse axis in the transverse plane, where n is an integer ranging from 1 or greater.

According to another embodiment, a method for acquiring MR signals from a sample includes: applying a B₀ field to the sample along a central axis while the sample is positioned in a transverse volume MR array coil, the transverse volume MR array coil comprising an M=0 mode coil and an M=n mode coil concentric with each other and coaxial with the central axis, where n is an integer ranging from 1 or greater; applying an excitation pulse to the sample utilizing one of the coils; applying a field gradient to the sample along a transverse axis orthogonal to the central axis; detecting a free induction decay (FID) from the sample on the M=0 mode coil; and after detecting the FID, detecting a geometric echo on the M=n mode coil.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a perspective, partially exploded view of an example of a transverse volume array coil according to some embodiments.

FIG. 2 is a perspective view of an example of an M=0 mode volume coil according to some embodiments.

FIG. 3 is a perspective view of an example of an M=1 mode transverse volume coil according to some embodiments.

FIG. 4 is a schematic view illustrating the current amplitude distribution of the M=1 mode transverse volume coil illustrated in FIG. 3.

FIG. 5 is a schematic view illustrating the B₁ field distribution in the transverse x-y plane of the M=1 mode transverse volume coil illustrated in FIG. 3.

FIG. 6 is a perspective view of an example of an M=2 mode transverse volume coil according to some embodiments.

FIG. 7 is a schematic view illustrating the B₁ field distribution in the transverse x-y plane of the M=2 mode transverse volume coil illustrated in FIG. 6.

FIG. 8 is a signal sequence diagram illustrating signals associated with an M=0 mode coil, M=1 mode coil, and x-gradient (Gₓ) coil as a function of time, in conjunction with an example of a method for acquiring MR signals from a sample according to some embodiments.

FIGS. 9A to 9H are schematic illustrations of the spin magnetizations of MR-active nuclei of a sample positioned in the volume of a transverse volume array coil as disclosed herein, at different times during operation thereof.

### DETAILED DESCRIPTION

The present disclosure introduces transverse volume coils useful for magnetic resonance (MR) applications. One or more transverse volume coils may form a part of a transverse volume array (“volary”) coil in which two or more coils are concentrically nested with each other and coaxial with a common z-axis. Each volume coil may have a cylindrical shape with openings along the z-axis to facilitate sample loading and nesting of multiple coils. One or more of the volume coils included in the array coil may have a conventional design, such as for example a fundamental mode (M=0) birdcage or millipede coil, having an electrically conductive coil geometry configured for generating a B₁ field profile that is uniform throughout the volume surrounded by the coil. One or more of the volume coils of the array coil may be a transverse volume coil having a coil geometry configured for generating a B₁ field profile that includes spatial harmonics along a transverse axis (e.g., x-axis) while being uniform along the other, orthogonal transverse axis (e.g., y-axis) as well as along the z-axis. A “y-axis” transverse volume coil may have the same geometry as an “x-axis” transverse volume coil, but its position is rotated ninety degrees in the transverse (x-y) plane relative to that of an x-axis transverse volume coil. The geometry of the transverse volume coil may be configured for one half of first order spatial harmonics (e.g., an M=1 mode coil), complete first order spatial harmonics (e.g., an M=2 mode coil), or for higher order spatial harmonics (M=3, 4, . . . mode coil). Coils with different spatial harmonics when utilized together have no magnetic mutual inductance with each other. Moreover, in a coil array including both an x-axis transverse volume coil and a y-axis transverse volume coil, these two coils have no magnetic mutual inductance with each other due to their physically orthogonal arrangement.

In a transverse volume array coil as disclosed herein, any one of the volume coils may be utilized to transmit RF excitation signals to the sample loaded in the array coil, and all coils may be utilized to receive MR measurement signals from the sample. Hence, a separate transmit-only coil is not needed, reducing the size, complexity and cost of the system. Imaging or spectral sensitivity may be improved by combining the signals received from the multiple volume coils of the array coil. Moreover, unlike known parallel acquisition techniques in which signals are received by individual coils simultaneously, in an array coil as disclosed herein signals are received by individual coils at slightly different times. Thus, the sample noises associated with the signals are incoherent, enabling any suitable signal averaging technique to be applied and increasing signal-to-noise ratio (SNR). In addition, because all volume coils in an array coil as disclosed herein are magnetically transparent from each other, no pin diodes or other active switching devices are needed, thereby significantly reducing coil complexity and cost. In addition, because the coils are volume coils they provide much more uniform RF profiles and better sensitivity coverage in the middle of the sample as compared to surface coils.

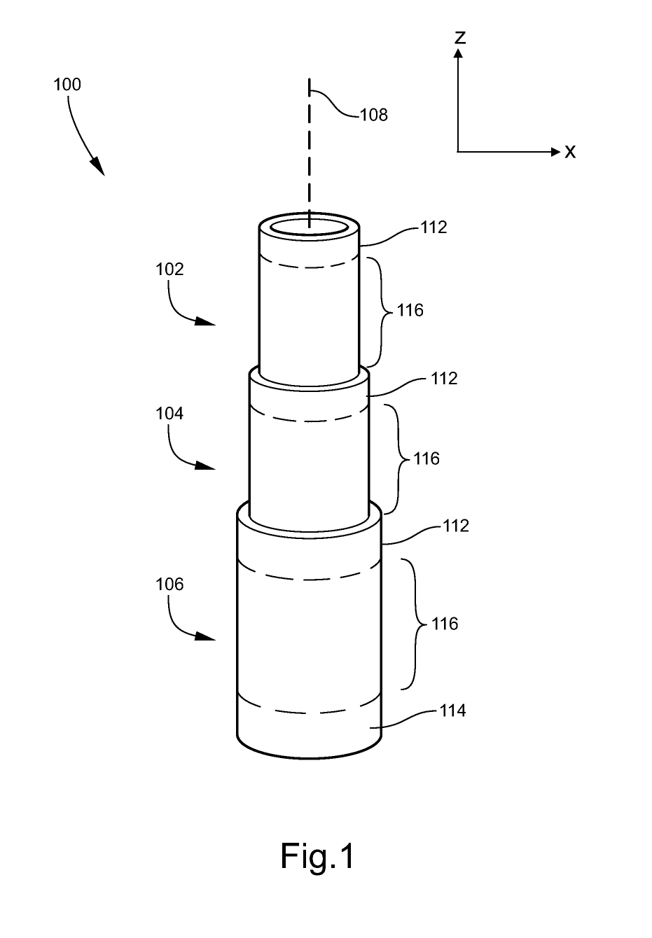

FIG. 1 is a perspective, partially exploded view of an example of a transverse volume array coil 100 according to some embodiments. The transverse volume array coil 100 includes a plurality of individual volume coils. Any number of individual volume coils may be provided. By example only, FIG. 1 illustrates a first volume coil 102, a second volume coil 104 and a third volume coil 106, with the understanding that two volume coils or more than three volume coils may be provided. The volume coils 102, 104 and 106 are shaped as cylinders and nested with each other. Hence, each volume coil 102, 104 and 106 is concentric with the other volume coils and all of the volume coils 102, 104 and 106 are coaxial with a common central (or longitudinal, or z-) axis 108 of the transverse volume array coil 100. To achieve concentric nesting, the first volume coil 102 (the inner coil in this example) has a smaller diameter than the second volume coil 104 (the middle coil), and the second volume coil 104 has a smaller diameter than the third volume coil 106 (or outer coil). The gaps between the volume coils 102, 104 and 106 in the radial direction may be minimal. In some embodiments, the volume coils 102, 104 and 106 may be isolated from each other in the radial direction by dielectric or electrically insulating structures positioned in the radial gaps. Such insulating structures may be substrates or coil formers (not specifically shown) on which the electrically conducting elements of the volume coils 102, 104 and 106 are disposed. More generally the volume coils 102, 104 and 106, and particularly the geometry or arrangement of the conductive elements of the volume coils 102, 104 and 106, may be fabricated by any suitable technique now known or later developed.

Each volume coil 102, 104 and 106 includes an arrangement of electrical conductors. The electrical conductors of each volume coil 102, 104 and 106 may include an upper ring 112, a lower ring 114, and a cylindrical RF sensitivity region 116 (or RF window) axially disposed between the upper ring 112 and the lower ring 114. The RF sensitivity region 116 may include a plurality (i.e., a geometry, arrangement, pattern, etc.) of legs (“elongated members” or “rungs”) extending through the cylindrical surface area of the RF sensitivity region 116. Some legs may be connected to the upper ring 112 while other legs may be connected to the lower ring 114. In the present context, the terms “upper” and “lower” are used in a relative sense only to distinguish the axially opposing positions of the upper ring 112 and lower ring 114, and not as a limitation on the orientation of the volume coils 102, 104 and 106 relative to any particular reference datum.

The partially exploded view of FIG. 1 is for illustrative purposes. In practice, the volume coils 102, 104 and 106 may be completely nested with each other. The volume coils 102, 104 and 106 may have the same or substantially the same overall (end-to-end) axial length. Moreover, the axial lengths of the respective upper rings 112, lower rings 114 and RF sensitivity regions 116 of the volume coils 102, 104 and 106 may have the same or substantially the same axial length, such that when nested their respective RF sensitivity regions 116 are aligned (i.e., do not overlap with any of the upper rings 112 or lower rings 114).

The transverse volume array coil 100 may include any combination of volume coils of differing spatial harmonic modes. One of the volume coils 102, 104 and 106 may be a fundamental mode (a zeroth order mode, or M=0 mode) coil. The M=0 mode coil may have any coil geometry, now known or later developed, configured for generating a B₁ field that is uniform over the entire cylindrical volume of the M=0 mode coil. Examples of M=0 mode coils include, but are not limited to, straight-legged birdcage coils (including millipede coils), solenoid coils, saddle coils, loop-gap resonators, Hemholtz coils, and slotted tube coils (e.g., Alderman-Grant style resonators). One or more of the volume coils 102, 104 and 106 may be a transverse volume coil having a coil geometry configured for generating a B₁ field with one-half first order spatial harmonics (e.g., an M=1 mode coil), complete first order spatial harmonics (e.g., an M=2 mode coil), or higher order spatial harmonics (M=3, 4, . . . mode coil) along a transverse (x or y) axis, examples of which are described below.

In some embodiments, the transverse volume array coil 100 is a two-element transverse (x- or y-axis) volume array coil in which one of the coils is an M=0 mode coil and the other coil is an nth mode (M=n) transverse volume coil exhibiting spatial harmonics, where n is an integer ranging from 1 or greater (i.e., an M=1, 2, 3, . . . mode coil). The nth mode transverse volume coil may be an x-axis or y-axis transverse volume coil. In other embodiments, the transverse volume array coil 100 is a three-element transverse (xy-axis) volume array coil (as shown in FIG. 1) in which one of the coils is an M=0 mode coil, another coil is an x-axis transverse volume coil of nth mode (n=1, 2, 3, . . . ), and another coil is a y-axis transverse volume coil of nth mode (n=1, 2, 3, . . . ). The mode order of the x-axis transverse volume coil may be the same as or different from the mode order of the y-axis transverse volume coil. As examples, both the x-axis and y-axis transverse volume coils may be M=1 or M=2 mode coils, or the x-axis transverse volume coil may be an M=1 mode coil while the y-axis transverse volume coil is an M=2 mode coil. In any of these embodiments, any of the coil resonance types (e.g., M=0 mode, M=1 mode, or M=2 mode) may be the inner coil or the outer coil, or the middle coil in the case of a three-element volume array coil. In any of these embodiments, any one of the volume coils 102, 104 and 106 may serve as the transmit coil and thus be placed in signal communication with the RF transmitter of an associated MRI or NMR spectrometer system. During operation, only one volume coil of the array coil 100 is needed to transmit RF excitation signals to a sample. Also during operation, all of the volume coils 102, 104 and 106 of the same array coil 100 may simultaneously serve as receive coils and thus each individual volume coil 102, 104 and 106 may be placed in signal communication with the RF receiver of the system.

In some embodiments of the transverse volume array coil 100, the volume coils 102, 104 and 106 may be tuned to the same resonance frequency. In other embodiments, one or more of the volume coils 102, 104 and 106 may be tuned to different resonance frequencies. As one example, a higher-order mode coil may be tuned to a resonance frequency different from that of the M=0 mode coil. Such a multiply resonant array coil may be provided with minimum inter-coil interaction.

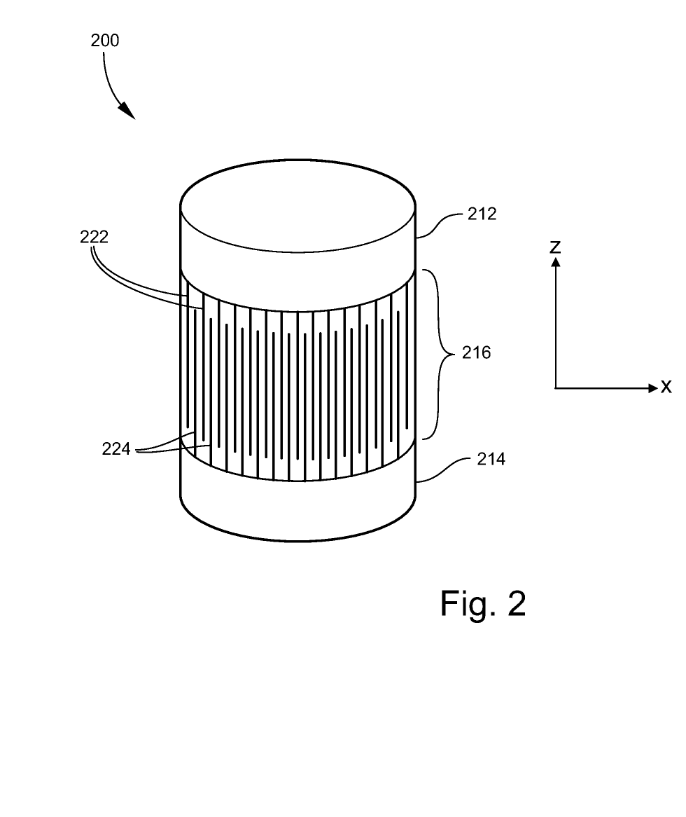

FIG. 2 is a perspective view of an example of an M=0 mode volume coil 200 according to some embodiments. In this specific yet non-limiting example, the M=0 mode volume coil 200 is a birdcage or millipede coil. The M=0 mode volume coil 200 has a cylindrical geometry coaxial with a central axis (z-axis). The M=0 mode volume coil 200 includes an electrically conductive upper ring 212, an electrically conductive lower ring 214, and a cylindrical RF sensitivity region 216 axially disposed between the upper ring 212 and the lower ring 214. The RF sensitivity region 216 includes a plurality of electrically conductive legs extending through the RF sensitivity region 216. The legs include a plurality of upper legs 222 connected to the upper ring 212 and a plurality of lower legs 224 connected to the lower ring 214. In this embodiment, the upper legs 222 and lower legs 224 are straight and are parallel with the central axis. The upper legs 222 are circumferentially spaced from each other about the central axis, and the lower legs 224 are circumferentially spaced from each other about the central axis. The circumferential spacing between the upper legs 222, and between the lower legs 224, may be a uniform distance. The upper legs 222 extend from the upper ring 212 toward the lower ring 214 over part of the axial length of the RF sensitivity region 216, such that the ends of the upper legs 222 are spaced from the lower ring 214 by an axial distance. The lower legs 224 extend from the lower ring 214 toward the upper ring 212 over part of the axial length of the RF sensitivity region 216, such that the ends of the lower legs 224 are spaced from the upper ring 212 by an axial distance.

The upper legs 222 and lower legs 224 are arranged in an interdigitated manner. That is, along the circumference of the RF sensitivity region 216, the legs alternate between being upper legs 222 and lower legs 224. In the present context, the “connection” between the upper legs 222 and the upper ring 212, and between the lower legs 224 and the lower ring 214, is a physical connection such that current is carried between the upper legs 222 and upper ring 212 and between the lower legs 224 and lower rings 214. Adjacent electrically conductive elements of the M=0 mode volume coil 200 separated by gaps may be capacitively coupled to each other. As noted above, the B₁ field generated by this type of RF coil is uniform over the entire cylindrical volume.

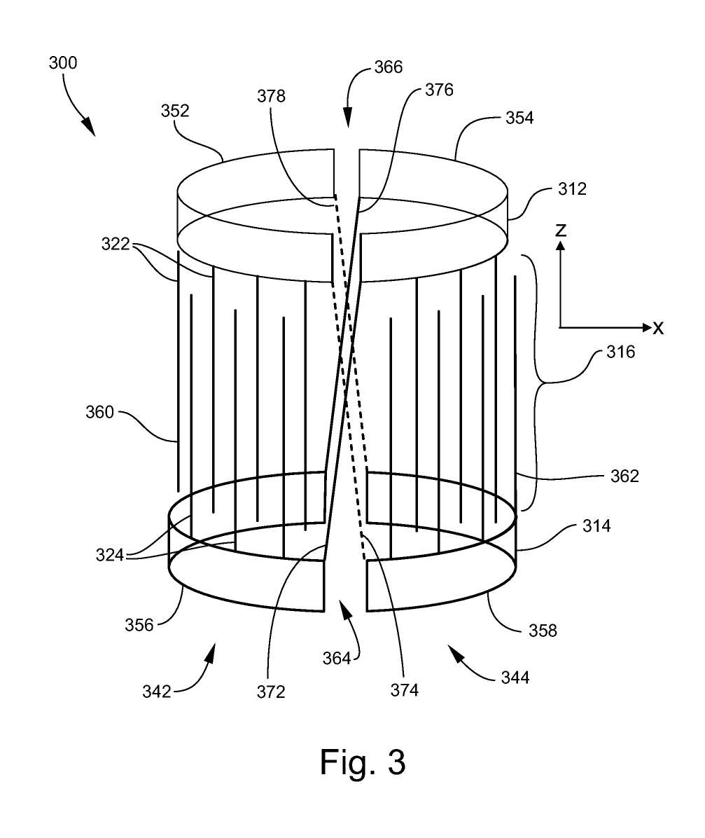

FIG. 3 is a perspective view of an example of an M=1 mode transverse volume coil 300 according to some embodiments. The M=1 mode transverse volume coil 300 includes an electrically conductive upper ring 312, an electrically conductive lower ring 314, and a cylindrical RF sensitivity region 316 axially disposed between the upper ring 312 and the lower ring 314. The RF sensitivity region 316 includes a plurality of electrically conductive legs extending through the RF sensitivity region 316. The legs include a plurality of upper legs 322 connected to the upper ring 312 and a plurality of lower legs 324 connected to the lower ring 314. The upper legs 322 and lower legs 324 may be straight and parallel with the central axis, and may be connected in an interdigitated manner generally similar to the M=0 mode coil 200 illustrated in FIG. 2. In this embodiment, however, the structure of the M=1 mode transverse volume coil 300 is divided or split along a longitudinal plane (the y-z plane in the illustrated example) into a plurality of cylindrical coil segments (two coil segments or halves 342 and 344 in the present embodiment). By this configuration, the upper ring 312 of the M=1 mode transverse volume coil 300 may be characterized as including a plurality of circumferentially spaced upper ring segments 352 and 354, lower ring segments 356 and 358, and RF sensitivity region segments (cylindrical segments) 360 and 362. Each upper ring segment 352 and 354 terminates at two ends, and each end of an upper ring segment is spaced from an end of an adjacent upper ring segment by a circumferential gap. Likewise, each lower ring segment 356 and 358 terminates at two ends, and each end of a lower ring segment is spaced from an end of an adjacent lower ring segment by a circumferential gap. The relative positions and spacing of the RF sensitivity region segments 360 and 362 may be characterized similarly. The gaps are “circumferential” in the sense that they have an arcuate distance in the transverse plane along the circumference occupied by the upper ring 312 or lower ring 314.

In the present embodiment, each coil segment 342 or 344 may be characterized as including an upper ring segment 352 or 354, a corresponding lower ring segment 356 or 358, and a corresponding RF sensitivity region segment 360 or 362 disposed axially between the upper ring segment 352 and 354 and lower ring segment 356 or 358. From the perspective of FIG. 3, each coil segment is spaced from an adjacent coil segment by a longitudinal gap 364 and 366 parallel to the central axis. Each longitudinal gap 364 and 366 is defined collectively by the circumferential gaps between adjacent pairs of upper ring segments 352 and 354, lower ring segments 356 and 358, and RF sensitivity segments 360 and 362. The size of each longitudinal gap 364 and 366 (i.e., the arc length in the transverse plane) may be minimal, for example 10 to 100 times smaller than the radius of the coil 300. The coil segments 342 and 344 of the M=1 mode transverse volume coil 300 may have the same dimensions (arc length in the transverse plane, axial length along to the central axis).

In the present embodiment, the M=1 mode transverse volume coil 300 may be characterized as being initially based on an M=0 mode coil structure such as described above and illustrated in FIG. 2, but with the coil structure cut into a desired number of coil segments (two equal halves in the present embodiment) along one or more longitudinal planes (one plane in the present embodiment). One coil segment is then flipped upside down, and the coil segments are brought back together so that there is a minimum gap between them. When one coil segment is flipped, one of the ring segments that was initially an upper ring segment after cutting becomes a lower ring segment after flipping, and the corresponding axially opposite ring segment that was initially a lower ring segment becomes an upper ring segment. After flipping, however, the electrical connections between the two original upper ring segments, and between the two original lower ring segments, remain unchanged. That is, after flipping, current continues to be able to flow between the two original upper ring segments (which are now a lower ring segment of the flipped coil segment and the upper ring segment of an adjacent, non-flipped coil segment), and between the two original lower ring segments (which are now an upper ring segment of the flipped coil segment and the lower ring segment of an adjacent, non-flipped coil segment).

In some embodiments, flipping a coil segment without changing the electrical connections to an adjacent, non-flipped coil segment may be implemented by providing some of the electrically conductive legs as elongated cross-members. The cross-members are added to the geometry of electrical conductors of the RF sensitivity region such that the cross-members electrically interconnect the original (i.e., before flipping) upper rings together and the original lower rings together. Thus, in the example illustrated in FIG. 3, a (first) cross-member 372 interconnects an end of the lower ring segment 356 of a (first) coil segment 342 and a corresponding end of the upper ring segment 354 of an adjacent (second) coil segment 344. To achieve this, the first cross-member 372 extends axially along the longitudinal gap 364 (over the axial length of the RF sensitivity region 316) and also traverses the longitudinal gap 364 in the transverse plane. Another (second) cross-member 374 interconnects an end of the upper ring segment 352 of the first coil segment 342 and a corresponding end of the lower ring segment 358 of the adjacent coil segment 344, spanning the same longitudinal gap 364 as the first cross-member 372. Hence, these two cross-members 372 and 374 “cross” each other in the longitudinal gap 364, and may be isolated from each other by dielectric or insulating material. Similarly, at a diametrically opposite location of the coil structure, another (third) cross-member 376 interconnects an end of the lower ring segment 356 of the first coil segment 342 and a corresponding end of the upper ring segment 354 of the adjacent coil segment 344. Another (fourth) cross-member 378 interconnects an end of the upper ring segment 352 of the first coil segment 342 and a corresponding end of the lower ring segment 358 of the adjacent coil segment 344, spanning the same longitudinal gap 366 as the third cross-member 376. The cross-members thus extend in directions that are non-parallel with the straight legs.

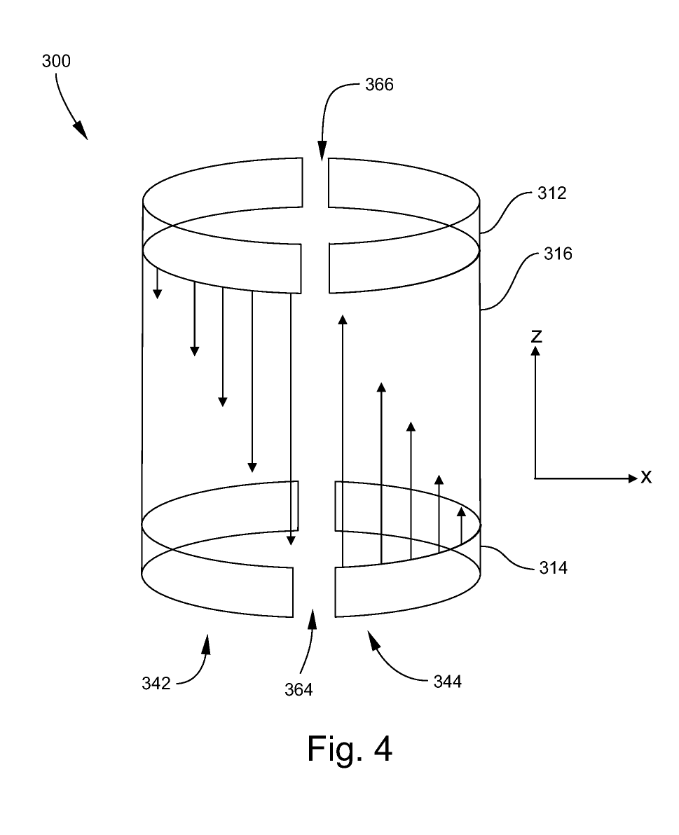

FIG. 4 is a schematic view illustrating the current amplitude distribution of the M=1 mode transverse volume coil 300 illustrated in FIG. 3. The resonance modes are setup as the same as a standard birdcage coil (e.g., as shown in FIG. 2) due to the identical boundary conditions. Sinusoidal current distribution is set up with the maximum current flow at the gap locations. Because one half of the coil is flipped, the directions of the current at both sides of the gap are opposite. The amplitude of the current reduces following a sinusoidal function to zero at the left and right extrema of the coil structure (from the perspective of FIG. 4), i.e., at the central regions of the coil segments 342 and 344.

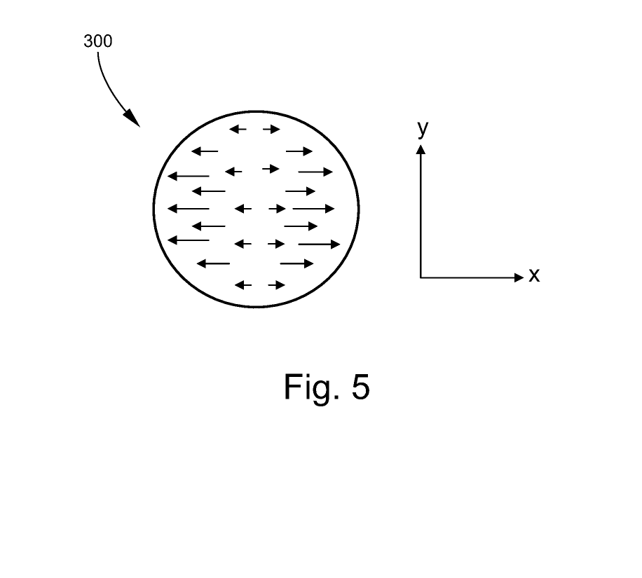

FIG. 5 is a schematic view illustrating the B₁ field distribution (or profile) in the transverse x-y plane of the M=1 mode transverse volume coil 300 illustrated in FIG. 3. The orientation of the x-axis and y-axis in the transverse x-y plane has been arbitrarily selected such that the spatial harmonics appear along the x-axis. By symmetry argument, the B₁ field (represented by field vectors) generated by the current distribution will have an x-axis component only and the field vectors are uniform on each y-z plane. The amplitude of the B₁ field along the gap between adjacent coil segments is zero due to the RF field cancelation. The direction of the B₁ field vectors at the left of the gap (negative x-direction) will be opposite to the direction of the B₁ field vectors at the right (positive x-direction). This B1 profile corresponds to one-half of the first-order spatial harmonics along the x-axis.

As noted above, the orientation of the x-axis and y-axis in the transverse x-y plane has been arbitrarily selected such that the spatial harmonics appear along the x-axis in FIG. 5. When so oriented, the M=1 mode transverse volume coil 300 may be referred to as an x-axis (or x-direction) transverse volume coil. It is evident that a y-axis (or y-direction) transverse volume coil may be realized by utilizing the geometry illustrated in FIG. 3 and rotating the coil structure ninety degrees in the transverse x-y plane. The current amplitude and B₁ field distributions shown in FIGS. 4 and 5, respectively, would then likewise be rotated ninety degrees. It is further evident that when nested together in an array coil, an x-axis transverse volume coil and a y-axis transverse volume coil will have zero mutual inductance due to their physical orthogonal arrangement. It will also be noted that the transverse volume coil is always a linear coil except for the case of the M=0 mode coil.

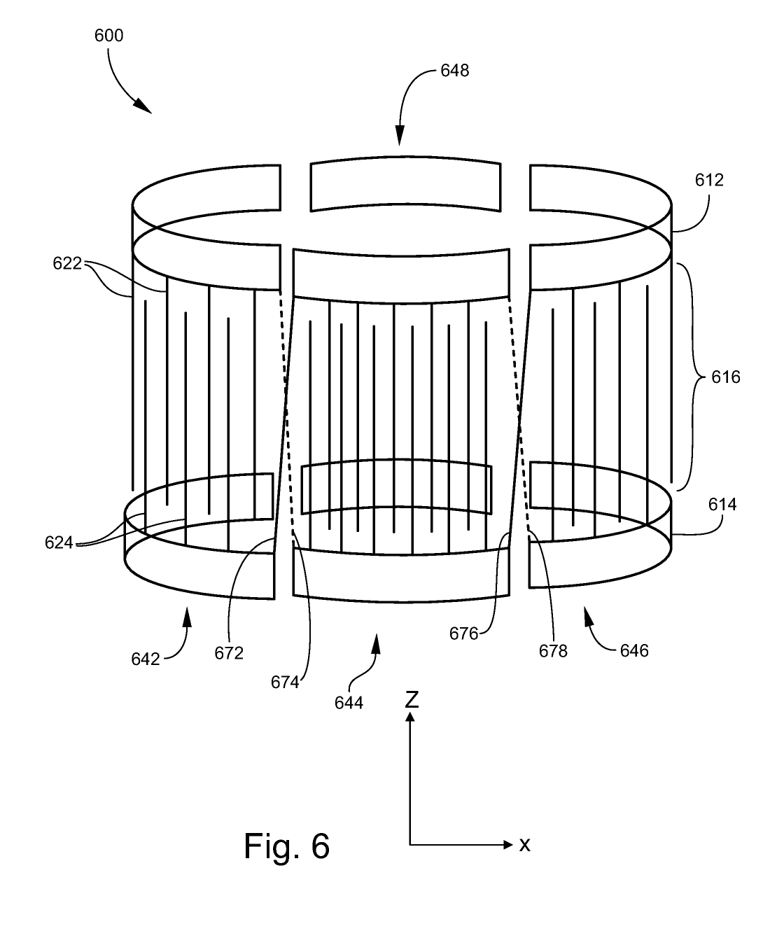

FIG. 6 is a perspective view of an example of an M=2 mode transverse volume coil 600. The M=2 mode transverse volume coil 600 includes an electrically conductive upper ring 612, an electrically conductive lower ring 614, and a cylindrical RF sensitivity region 616 axially disposed between the upper ring 612 and the lower ring 614. The RF sensitivity region 616 includes a plurality of electrically conductive legs extending through the RF sensitivity region 616. The legs include a plurality of upper legs 622 connected to the upper ring 612 and a plurality of lower legs 624 connected to the lower ring 614. The upper legs 622 and lower legs 624 may be straight and parallel with the central axis, and may be connected in an interdigitated manner generally similar to the M=0 mode coil illustrated in FIG. 2. In this embodiment, however, the M=2 mode transverse volume coil is divided along two orthogonal longitudinal planes into four cylindrical coil segments 642, 644, 646 and 648, which may be of equal dimensions. By this configuration, the M=2 mode transverse volume coil 600 may be characterized as including four circumferentially spaced upper ring segments, four lower ring segments, and four RF sensitivity region segments. Similar to the coil structure described above and illustrated in FIG. 3, adjacent upper ring segments are spaced from each other by circumferential gaps, adjacent lower ring segments are spaced from each other by corresponding circumferential gaps, and adjacent RF sensitivity region segments are spaced from each other by corresponding circumferential gaps. Also similar to the embodiment of FIG. 3, each coil segment may be characterized as including an upper ring segment, a corresponding lower ring segment, and a corresponding RF sensitivity region segment disposed axially between the upper ring segment and lower ring segment.

The M=2 mode transverse volume coil 600 may be characterized as being initially based on an M=0 mode coil structure such as described above and illustrated in FIG. 2, but with the coil structure cut along two orthogonal longitudinal planes to form four coil segments 642, 644, 646 and 648. Two opposing coil segments are then flipped upside down relative to the other two opposing coil segments, and the coil segments are brought back together so that there is a minimum gap between them. Similar to embodiment of FIG. 3, after flipping the original electrical connections are preserved. This again may be implemented by adding a plurality of electrically conductive elongated cross-members to the geometry of electrical conductors of the RF sensitivity region, such that the cross-members electrically interconnect the original upper rings together and the original lower rings together. Thus, in the example illustrated in FIG. 6, a first cross-member 672 interconnects an end of the lower ring segment of a first coil segment 642 and a corresponding end of the upper ring segment of an adjacent second coil segment 644, traversing or spanning the corresponding longitudinal gap in a direction non-parallel with the central axis as described above. A second cross-member 674 interconnects an end of the upper ring segment of the first coil segment 642 and a corresponding end of the lower ring segment of the adjacent second coil segment 644, spanning the same longitudinal gap as the first cross-member 672. A third cross-member 676 interconnects an end of the lower ring segment of the second coil segment 644 and a corresponding end of the upper ring segment of an adjacent third coil segment 646. A fourth cross-member 678 interconnects an end of the upper ring segment of the second coil segment 644 and a corresponding end of the lower ring segment of the adjacent third coil segment 646. In a similar manner, fifth and sixth cross-members (not shown) connect the upper and lower ring segments of the third coil segment 646 and an adjacent fourth coil segment 648 in a cross-wise manner, and seventh and eighth cross-members (not shown) connect the upper and lower ring segments of the fourth coil segment 648 and the adjacent first coil segment 642 in a cross-wise manner.

As a result of the coil geometry of the M=2 mode transverse volume coil 600 illustrated in FIG. 6, the first-order resonance mode has a periodic (sinusoidal in the present example) current distribution of 4π (720 degrees) around the circumference of the coil structure. As in the case of the one-half first-order resonance mode embodiment illustrated in FIG. 3, the current maxima are set at the gap locations. The current magnitude reaches zero at the middle of the coil structure (the central regions of the coil segment 644 and 648) and at the two extrema (the central regions of the coil segments 642 and 646). The directions of the current in the “flipped” coil segments are opposite to the directions of the current in the “unflipped” coil segments.

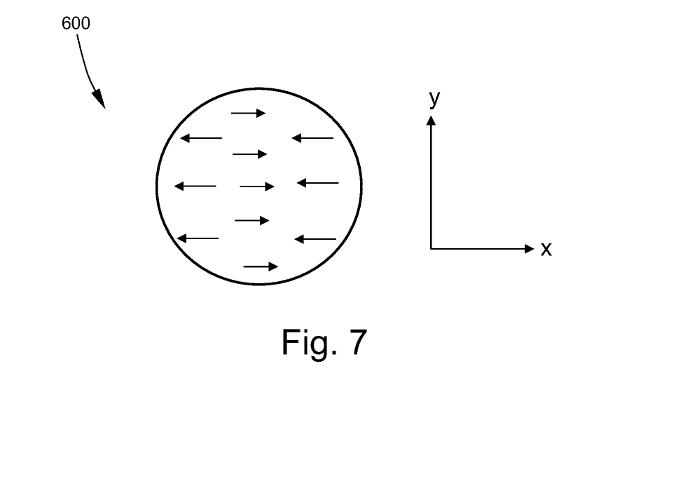

FIG. 7 is a schematic view illustrating the B₁ field distribution (or profile) in the transverse x-y plane of the M=2 mode transverse volume coil 600 illustrated in FIG. 6. The orientation of the x-axis and y-axis in the transverse x-y plane has been arbitrarily selected such that the spatial harmonics appear along the x-axis. By symmetry argument, the B₁ field (represented by field vectors) generated by the current distribution will have an x-axis component only and the field vectors are uniform on each y-z plane. The amplitude of the B₁ field along the gaps is zero due to the field cancelation at these locations. The directions of the B₁ field vectors follow an alternating pattern (negative and positive directions along the x-axis) as shown in FIG. 7. This B1 profile corresponds to complete first-order spatial harmonics along the x-axis.

In the example illustrated in FIGS. 6 and 7, the M=2 mode transverse volume coil 600 is an x-axis transverse volume coil. A y-axis M=2 mode transverse volume coil may be realized by rotating the coil structure of FIG. 6 ninety degrees in the transverse x-y plane. As noted above, an x-axis transverse volume coil and y-axis transverse volume coil when nested together as an array coil will have zero mutual inductance due to their physical orthogonal arrangement. Moreover, the M=2 mode transverse volume coil (either x-axis or y-axis) when nested together with an M=0 mode coil and/or M=1 mode coil will have zero mutual inductance with such coils.

The coil design concepts described above with reference to FIGS. 3-7 may be expanded to realize higher-order (M=3, 4, . . . ) mode transverse volume coils by providing additional flipped/unflipped coil segments and cross-members.

An example of a method for acquiring MR signals from a sample will now described. In the present context, the term “sample” encompasses any object from which MR signals may be acquired, i.e., an object containing MR-active nuclei. The “sample” may, for example, be a patient positioned in an MRI system. In this example, a two-element transverse x-axis volume array coil is utilized, and includes an M=0 mode coil and M=1 mode coil as described above. The individual volume coils are tuned to the same RF frequency to obtain parallel MR measurements from the sample. The transverse x-axis volume array coil may be installed in an appropriately configured MR (MRI or NMR) system as appreciated by persons skilled in the art. The MR system may, for example, include a magnetic field gradient coil system with x-direction (Gₓ), y-direction (G_{y}), and z-direction (G_{z}) gradient coils and gradient control electronics. The gradient coils typically surround the volume array coil and may be of any design now known or later developed. A magnet configured for generating a strong static magnetic B₀ field surrounds the gradient coils and volume array coil. The MR system may further include RF transmit electronics and RF receive electronics in signal communication with the volume array coil, hardware and software for data acquisition and signal processing, and an electronic processor-based controller for controlling the MR system and managing user input and output.

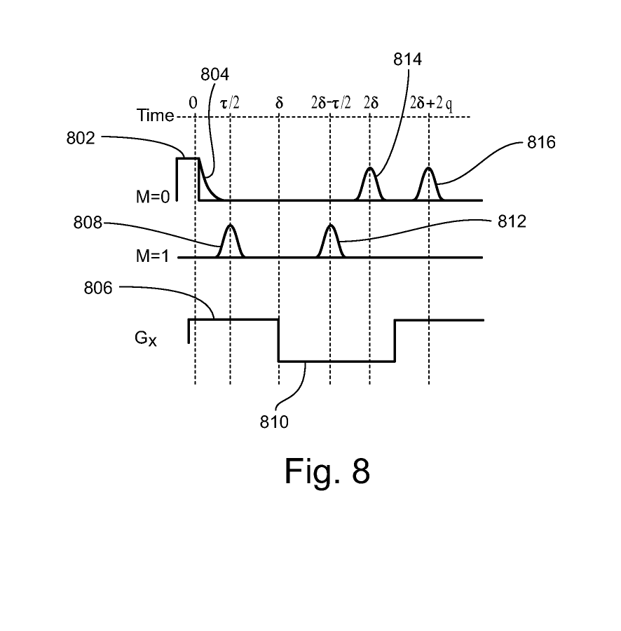

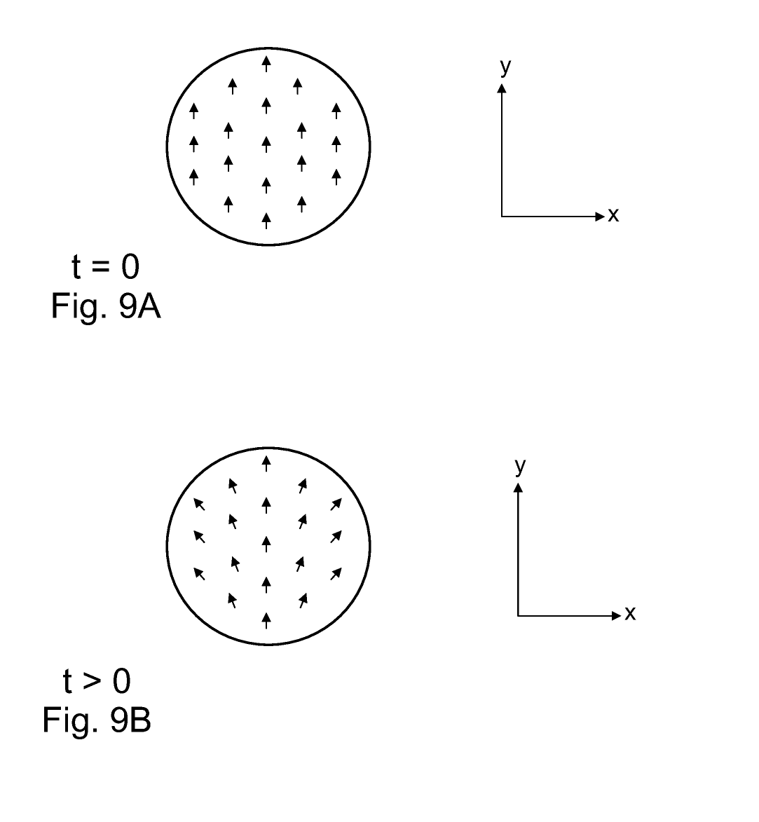

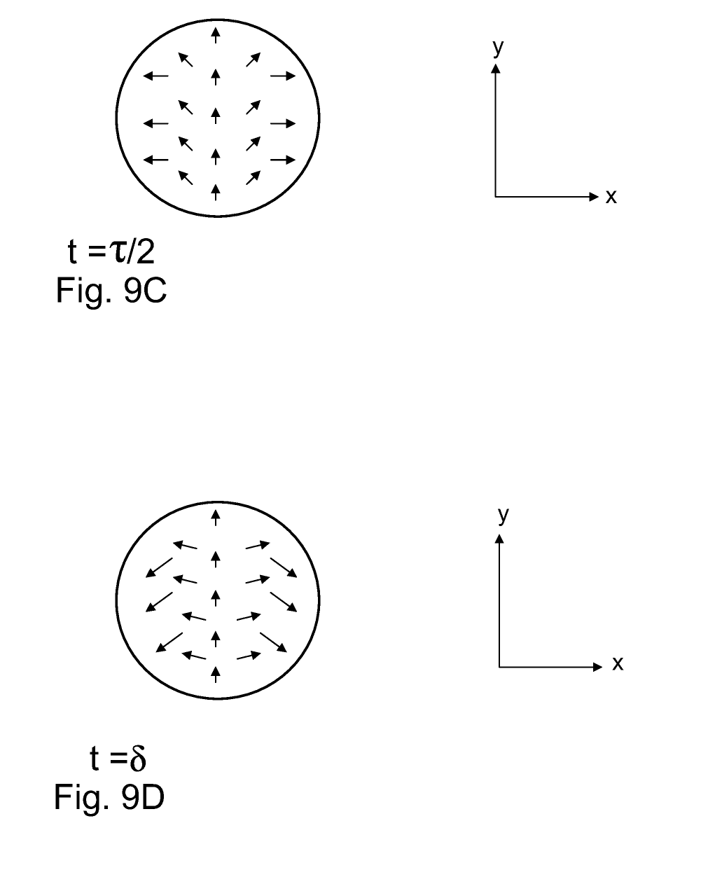

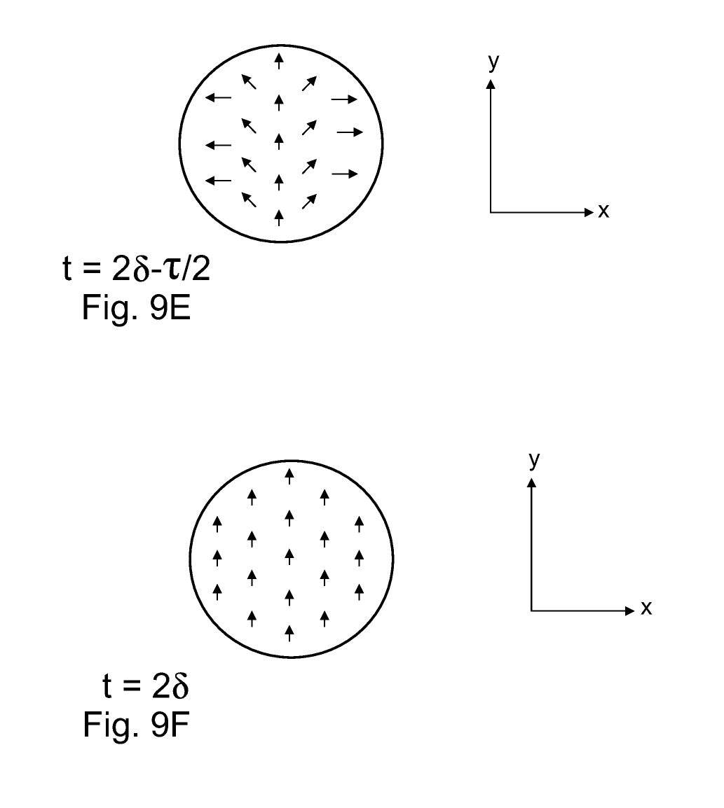

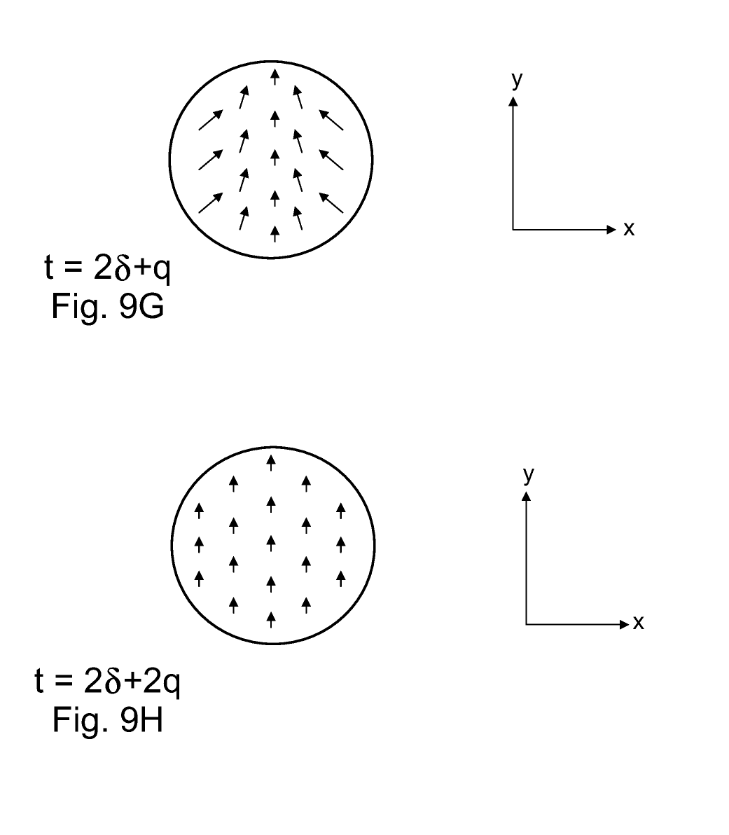

The method is described with reference to FIGS. 8 to 9C. Specifically, FIG. 8 is a signal sequence diagram illustrating signals associated with the M=0 mode coil, the M=1 mode coil, and the x-gradient (Gₓ) coil as a function of time. FIGS. 9A to 9H are schematic illustrations, from the perspective of the transverse x-y plane of the volume array coil, of the spin magnetizations of MR-active nuclei of a sample positioned in the volume of the volume array coil, at different times during operation thereof. In relation to the progression of time shown in FIG. 8, the times are: t=0 (FIG. 9A); t>0 (FIG. 9B); t=τ/2 (FIG. 9C); t=δ (FIG. 9D); t=2δ−Σ/2 (FIG. 9E); t=2δ (FIG. 9F); t=2δ+q (FIG. 9G); and t=2δ+2q (FIG. 9H). The method generally follows a pulse, gradient, and data acquisition sequence. That is, an excitation pulse is applied, field gradients are applied, and signals from the free induction decay (FID) and ensuing echoes are collected. The sequence may be repeated any number of times as needed to obtain acceptable spectral or imaging data.

In this example, the axis along which the static B₀ field is applied is taken to be the z-axis. The volume array coil is positioned in the B₀ field such that its central axis corresponds to the z-axis. Hence, the nuclear spins in the sample are initially aligned with the B₀ field along the z-axis. The pulse sequence may start with application of an RF excitation pulse utilizing one of the coils. In the present example, a y-direction pw90 pulse 802 (ninety degree RF excitation pulse) is applied on the M=0 mode coil. In imaging applications, slice selection on the sample may be performed at the start of the pulse sequence. Slice selection may be performed by applying a slice selection magnetic field gradient pulse (not shown in FIG. 8) in a desired direction, which in this example is the z-direction (a G_{z} gradient, not shown in FIG. 8), while applying the pw90 pulse 802. The y-direction pw90 pulse 802 flips the spins ninety degrees down to the transverse plane with all spins aligned along the y-axis as shown in FIG. 9A. As a result of the pw90 pulse 802 the sample emits an FID signal 804, which is detected by the M=0 mode coil. Immediately after applying the slice selection pulse and pw90 pulse 802, an x-gradient pulse 806 is turned on at time t=0. FIG. 9B depicts the spins after the start of the x-gradient pulse 806, at an arbitrary time between t=0 and t=τ/2. The spins at the center region of the sample volume do not rotate (i.e., remain aligned with the y-axis). The spins to the right of center rotate clockwise while the spins to the left of center rotate counterclockwise. FIG. 9C depicts the spins at time t=τ/2. The value of τ is determined by the relation τ=2π/(γG*FOV), where γ is the gyromagnetic ratio of the nucleus being irradiated, G is the magnitude of the gradient being applied (in this example, the x-gradient or Gₓ), and FOV (field of view) is the axial length of the RF sensitivity region of the volume array coil. At time t=τ/2, the pattern of the x-component of the spins matches the B₁ profile of the M=1 mode coil, as evident by comparing FIG. 9C with FIG. 5. Due to this matching, the M=1 mode coil detects a “geometric” echo 808.

At a time t=δ, the direction of the x-gradient is reversed as indicated by a reversed gradient pulse 810 in FIG. 8. The reversed gradient causes the spins to rotate in the opposite sense. At a subsequent time t=2δ−τ/2 (FIG. 9E), the spins have rotated back to the alignment pattern shown in FIG. 9C, and consequently a geometric echo 812 will reappear at the M=1 mode coil. Subsequently, at time t=2δ (FIG. 9F), the spins have rotated back to the alignment pattern shown in FIG. 9A, and a gradient echo 814 appears at the M=0 mode coil. The direction of the x-gradient may then be reversed at time t=2δ+q. Realignment of the spins at time t=2d+2q (FIG. 9H) back to the pattern shown in FIG. 9A gives rise to another gradient echo 816. The entire gradient echo sequence may be repeated any number of times within T2 (transverse relaxation).

As evident from FIG. 8, the volume array coil receives four signals during each gradient/reverse gradient cycle. The signals received at the individual coils may be summed to improve sensitivity. While the signals are received generally in parallel, they are received at slightly different times. Accordingly, the respective noise components attending these signals are not coherent and thus may be averaged out during signal processing.

From the present disclosure, additional and/or alternative embodiments of the above-described example of a method will be appreciated. In some embodiments, a two-element transverse volume array coil is utilized in which the M=1 mode coil is a y-axis transverse volume coil, and a y-direction gradient is applied to produce echoes. In other embodiments, the method is extended to use of a three-element transverse volume array coil that may include an x-axis M=1 mode coil and a y-axis M=1 mode coil. The method may also be extended to use of a transverse volume array coil that includes more than three individual volume coils. In other embodiments, the method is extended to use of one or more M=2 or higher-order volume coils from which a greater number of MR measurement signals may be obtained during a given gradient pulse cycle.

In the above description, the subject matter disclosed herein is presented primarily in the context of MRI systems. It will be understood, however, that the subject matter may be readily applied to NMR spectrometry.

It will be understood that terms such as “communicate” and “in . . . communication with” (for example, a first component “communicates with” or “is in communication with” a second component) are used herein to indicate a structural, functional, mechanical, electrical, signal, optical, magnetic, electromagnetic, ionic or fluidic relationship between two or more components or elements. As such, the fact that one component is said to communicate with a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

What is claimed is:

1. A transverse volume magnetic resonance (MR) coil, comprising:
an electrically conductive upper ring coaxial with a central axis;
an electrically conductive lower ring coaxial with the central axis and axially spaced from the upper ring; and
a plurality of electrically conductive legs extending through a cylindrical region axially disposed between the upper ring and the lower ring, wherein the legs are arranged in a geometry configured for generating a B₁ field comprising nth mode spatial harmonics along a first transverse axis in a transverse plane orthogonal to the central axis, where n is an integer ranging from 1 or greater, and wherein the B₁ field is uniform along a second transverse axis orthogonal to the first transverse axis in the transverse plane.

2. The transverse volume MR coil of claim 1, wherein the geometry is configured for generating one-half first order spatial harmonics or complete first order spatial harmonics.

3. The transverse volume MR coil of claim 1, wherein the plurality of legs comprises a plurality of upper legs connected to the upper ring and a plurality of lower legs connected to the lower ring.

4. The transverse volume MR coil of claim 3, wherein the upper legs and the lower legs are parallel with the central axis.

5. The transverse volume MR coil of claim 3, wherein the upper legs and the lower legs are arranged in an interdigitated manner around the cylindrical region.

6. The transverse volume MR coil of claim 1, wherein:
the upper ring comprises a plurality of upper ring segments circumferentially spaced about the central axis;
the lower ring comprises a plurality of lower ring segments circumferentially spaced about the central axis;
the cylindrical region comprises a plurality of cylindrical segments circumferentially spaced about the central axis, each cylindrical segment comprising a respective portion of the plurality of legs;
the upper ring segments, the lower ring segments, and the cylindrical segments form a plurality of coil segments, each coil segment spaced from an adjacent coil segment by a longitudinal gap parallel to the central axis;
the plurality of legs comprises a plurality of upper legs extending from the upper ring segments toward respective lower ring segments, and a plurality of lower legs extending from the lower ring segments toward respective upper ring segments; and
the plurality of legs further comprises a plurality of cross-members, each cross-member interconnecting an end of a respective lower ring segment with an end of the upper ring segment of an adjacent coil segment, and each cross-member extending in a direction traversing a corresponding longitudinal gap.

7. The transverse volume MR coil of claim 6, comprising two or four coil segments.

8. A transverse volume magnetic resonance (MR) array coil, comprising a plurality of cylindrical coils concentric with each other and coaxial with a common central axis, wherein at least one of the coils is a transverse volume MR coil according to claim 1.

9. The transverse volume MR array coil of claim 8, wherein the plurality of cylindrical coils comprises an M=0 mode coil.

10. The transverse volume MR array coil of claim 8, wherein the plurality of cylindrical coils comprises a first transverse volume MR coil according to claim 1 and a second transverse volume MR coil according to claim 1, and wherein the respective geometries of the first transverse volume MR coil and the second transverse volume MR coil are orthogonal in the transverse plane.

11. A transverse volume magnetic resonance (MR) array coil, comprising:
a first coil comprising a cylindrical first geometry of electrical conductors coaxial with a central axis, wherein the first geometry is configured for generating a B₁ field that is uniform throughout a transverse plane orthogonal to the central axis; and
a second coil comprising a cylindrical second geometry of electrical conductors concentric with the first coil relative to the central axis, wherein the second geometry is configured for generating a B1 field comprising nth mode spatial harmonics along a first transverse axis in the transverse plane while being uniform along a second transverse axis orthogonal to the first transverse axis in the transverse plane, where n is an integer ranging from 1 or greater.

12. The transverse volume MR coil of claim 11, comprising a third coil comprising a cylindrical third geometry of electrical conductors concentric with the first coil and the second coil relative to the central axis, wherein the third geometry is configured for generating a B1 field comprising nth mode spatial harmonics along the second transverse axis while being uniform along the first transverse axis.

13. The transverse volume MR coil of claim 11, wherein the mode of the second coil is the same as the mode the third coil.

14. The transverse volume MR coil of claim 11, wherein the mode of the second coil is different from the mode the third coil.

15. A method for acquiring magnetic resonance (MR) signals from a sample, the method comprising:
applying a B₀ field to the sample along a central axis while the sample is positioned in a transverse volume MR array coil, the transverse volume MR array coil comprising an M=0 mode coil and an M=n mode coil concentric with each other and coaxial with the central axis, where n is an integer ranging from 1 or greater;
applying an excitation pulse to the sample utilizing one of the coils;
applying a field gradient to the sample along a transverse axis orthogonal to the central axis;
detecting a free induction decay (FID) from the sample on the M=0 mode coil; and
after detecting the FID, detecting a geometric echo on the M=n mode coil.

16. The method of claim 15, comprising, before applying the field gradient, applying a slice selection pulse to the sample.

17. The method of claim 15, wherein detecting the geometric echo occurs at a time nt/2, n is an integer and τ=2π/(γG*FOV), where γ is the gyromagnetic ratio of a nucleus of the sample, G is the magnitude of the field gradient, and FOV is the axial length of a field of view of the transverse volume MR array coil.

18. The method of claim 15, comprising, after detecting the geometric echo, reversing the field gradient and detecting an additional geometric echo on the M=n mode coil.

19. The method of claim 15, comprising repeating the steps of applying the ninety degree pulse, applying the field gradient, detecting the FID, and detecting the geometric echo one or more times.

20. The method of claim 15, comprising:
before applying the field gradient, applying a slice selection pulse to the sample;
after detecting the geometric echo, selecting a different slice by applying another slice selection pulse to the sample; and
repeating the steps of applying the ninety degree pulse, applying the field gradient, detecting the FID, and detecting the geometric echo one or more times.
